(19) United States
(12) Patent Application Publication
(10) Pub. No.: US 2013/0015504 A1
(43) Pub. Date: Jan. 17, 2013

(54) TSV STRUCTURE AND METHOD FOR FORMING THE SAME

(71) Applicants: Chien-Li Kuo, Hsinchu City (TW); Chin-Sheng Yang, Hsinchu City (TW); Ming-Tse Lin, Hsinchu City (TW)

(72) Inventors: Chien-Li Kuo, Hsinchu City (TW); Chin-Sheng Yang, Hsinchu City (TW); Ming-Tse Lin, Hsinchu City (TW)

(21) Appl. No.: 13/179,577

(22) Filed: Jul. 11, 2011

(51) Int. Cl. H01L 23/48; H01L 29/06; H01L 21/768; H01L 29/772

(52) U.S. Cl. 257/213; 257/774; 257/508; 438/637; 257/E23.011; 257/E29.242; 257/E29.006; 257/E21.597

(57) ABSTRACT

A TSV structure includes a wafer including a first side and a second side, a through via connecting the first side and the second side, a through via dielectric layer covering the inner wall of the through via, a conductive layer which fills up the through via and consists of a single material to be a seamless TSV structure, a first dielectric layer covering the first side and surrounding the conductive layer as well as a second dielectric layer covering the second side and part of the through via dielectric layer but partially covered by the conductive layer.

### BACKGROUND OF THE INVENTION

1. Field of the Invention

The present invention generally relates to a TSV (through-silicon via) structure and the method for forming the TSV structure. In particular, the present invention generally relates to a method to fall into the formation of the TSV structure after the formation of CMOSs and to form a through via dielectric layer before the formation of CMOSs in order to avoid the problems of BEOL jeopardizing the TSV structure to cause pumping and to avoid the problem of copper contamination owing to wafer thinning.

2. Description of the Prior Art

The through-silicon via technique is a quite novel semiconductor technique. The through-silicon via technique mainly resides in solving the problem of the electrical interconnection of chips and belongs to anew 3D packing field. The hot through-silicon via technique creates the products which better meet the market trends of “light, thin, short and small” by the 3D stacking through the through-silicon via, to provide the micro electronic mechanic system (MEMS), the photoelectronics and electronic elements with packing techniques of wafer-level package.

The through-silicon via technique drills holes in the wafer by etching or by laser then fills the holes with conductive materials, such as copper, polysilicon or tungsten to form vias, i.e. conductive channels connecting inner regions and outer regions. At last, the wafer or the dice is thinned to be stacked or bonded together to be a 3D stack IC. In such a way, the wire bonding procedure may be omitted. Using etching or laser to form conductive vias not only omits the wire bonding but also shrinks the occupied area on the circuit board and the volume for packing.

The inner connection distance of the package by the through-silicon via technique, i.e. the thickness of the thinned wafer or the dice, compared with the conventional stack package of wire bonding type, the 3D stack IC has much shorter inner connection distance, so the 3D stack IC performs better in many ways, such as smaller electrical resistance, faster transmission, lower noise and better performance. Especially for the CPU, flash memory and memory card, the advantages of the shorter inner connection distance of the through-silicon via technique are much more outstanding. In addition, the package size of the 3D stack IC equals to the size of the dice, so the through-silicon via technique is more valuable in the portable electronic devices.

For the current process and techniques, the through-silicon via technique may divided into two types, namely the via first or the via last. The via first process further includes two variations, called before CMOS and after CMOS. In the via-first-before-CMOS process, through-silicon holes are formed on the silicon wafer and filled with a conductive material before the formation of the CMOS. Considering the high temperature procedures in the later CMOS process, the selection of the conductive material is basically focused on those which can survive after high temperatures, such as poly silicon, rather than the better copper because copper tends to form pumping and is unable to keep a low electrical resistance after being subject to thermal processes over and over again. To be viewed as a whole, the via-first-before-CMOS process is more compatible with the conventional CMOS process. However, the conductive material must bear high temperatures.

In the via-first-after-CMOS process, the formation of the via and the filling of the conductive metal are done after the completion of the CMOS process. The current choice of the conductive metal is copper, which is much better than poly silicon in conductivity concern. Because the filling of copper may fail due to the formation of void, tungsten gradually becomes an alternative choice. To be viewed as a whole, the filling of copper is particularly difficult and there is possible contamination of copper because the CMOS is completed, which makes it less compatible with the conventional CMOS process.

On top of them, a chemical mechanical polishing step may also have adverse influence on a finished interlayer dielectric layer. Given the above, a novel method to make a novel through-silicon via structure as well as a novel through-silicon via structure are still needed. In this novel method, copper has the chance to replace the less conductive poly silicon in the through-silicon via structure without the concerns of adverse issues. In addition, the completion of the CMOS will not hinder the planarization of the copper after the filling of copper.

### SUMMARY OF THE INVENTION

The present invention as a result proposes a novel method to make a novel through-silicon via structure as well as a novel through-silicon via structure. The novel through-silicon via structure of the present invention is a seamless through-silicon via structure. Because there is no conventional silicon sandwiched between the conductive layer and the inner wall of the through via, a through-silicon via structure of smaller size maybe obtained even though the size of the conductive material layer is not changed and the performance of the element is not compromised. Even though the copper of better conductivity replaces the poly-Si in the novel through-silicon via structure of the present invention, there is no problem of difficulty filling the through-silicon via with copper, possible contamination of copper or thinning the wafer after the MOS procedure is completed. In addition, the copper in the through via may also avoid the problem of pumping owing to being repeatedly subjected to thermal procedures.

The present invention in a first aspect proposes a through-silicon via structure. The through-silicon via structure of the present invention includes a wafer, a through via, a through via dielectric layer, a conductive layer, a first dielectric layer, and a second dielectric layer. The wafer includes a substrate, a first side and a second side. The through via is disposed in the substrate and connects the first side and the second side. The through via dielectric layer covers the inner wall of the through via. The conductive layer which fills up the through via consists of a single material, to be a seamless through-silicon via structure. The first dielectric layer covers the first side and surrounds the conductive layer. The second dielectric layer covers the second side and part of the through via dielectric layer but is partially covered by the conductive layer.

The present invention in a second aspect proposes a through-silicon via structure. The through-silicon via structure of the present invention includes a wafer, a through via, a through via dielectric layer, a conductive layer, a first dielectric layer, an interconnection structure and a plug. The wafer includes a substrate, a first side and a second side. The through via is disposed in the wafer and connecting the first side and the second side. The through via dielectric layer covers the inner wall of the through via. The conductive layer fills up the through via. The first dielectric layer covers the first side. The interconnection structure is disposed in the first dielectric layer and covers the conductive layer. The plug penetrates the first dielectric layer to electrically connect the conductive layer and the interconnection structure.

The present invention in a third aspect proposes a through-silicon via structure. The through-silicon via structure of the present invention includes a wafer, a through via, a substrate column, a through via dielectric ring, a first conductive ring and a first dielectric ring. The wafer includes a first side and a second side. The through via is disposed in the wafer and connects the first side and the second side. The substrate column fills up the through via so that the through via dielectric ring surrounds and directly contacts the substrate column. The first conductive ring surrounds and directly contacts the through via dielectric ring. The first dielectric ring surrounds and directly contacts the first conductive ring, and is further surrounded by the wafer.

The present invention in a fourth aspect proposes a through-silicon via structure. The through-silicon via structure of the present invention includes a wafer, an active area, a through via, a conductive layer, a dielectric layer, at least one active element, an interconnection structure and a body contact. The wafer includes a first side and a second side. The active area is disposed on the first side. The through via is disposed in the wafer and connects first side and said second side. The conductive layer fills up the through via. The dielectric layer covers the first side and at least one active element is disposed in the active area, on the dielectric layer and right above the conductive layer. The interconnection structure is disposed in an interlayer dielectric layer and on the at least one active element. Besides, the body contact is disposed in the active area, penetrates the dielectric layer to electrically connect the conductive layer and the interconnection structure.

The present invention in a fifth aspect proposes a through-silicon via structure. The through-silicon via structure of the present invention includes a wafer, a through via, a through via dielectric layer, a conductive layer, a dielectric layer, a conductive cap, an interconnection structure and a plug. The wafer includes a first side and a second side. The through via is disposed in the wafer and connects the first side and the second side. The through via dielectric layer covers the inner wall of the through via. The conductive layer fills the through via. The dielectric layer partially covers the first side. The conductive cap is disposed on the first side, in the interlayer dielectric layer, indirect contact with and completely covers the conductive layer. The interconnection structure is disposed in the dielectric layer and covers the conductive cap. The plug is disposed in the dielectric layer to electrically connect the conductive cap and the interconnection structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-8 illustrate the method for forming a through-silicon via (TSV) structure of the present invention.

### DETAILED DESCRIPTION

The present invention in a first aspect provides a method for forming a through-silicon via (TSV) structure. In the method of the present invention copper fills the through via after the completion of CMOS. Copper has a much better conductivity and serves as the conductive medium to replace poly-Si. In addition, the problems of copper filling and copper contamination owing to wafer thinning are avoided. What is more, the copper in the through via may also avoid the problem of pumping owing to repeatedly subject to thermal procedures because the copper is filled after the completion of CMOS.

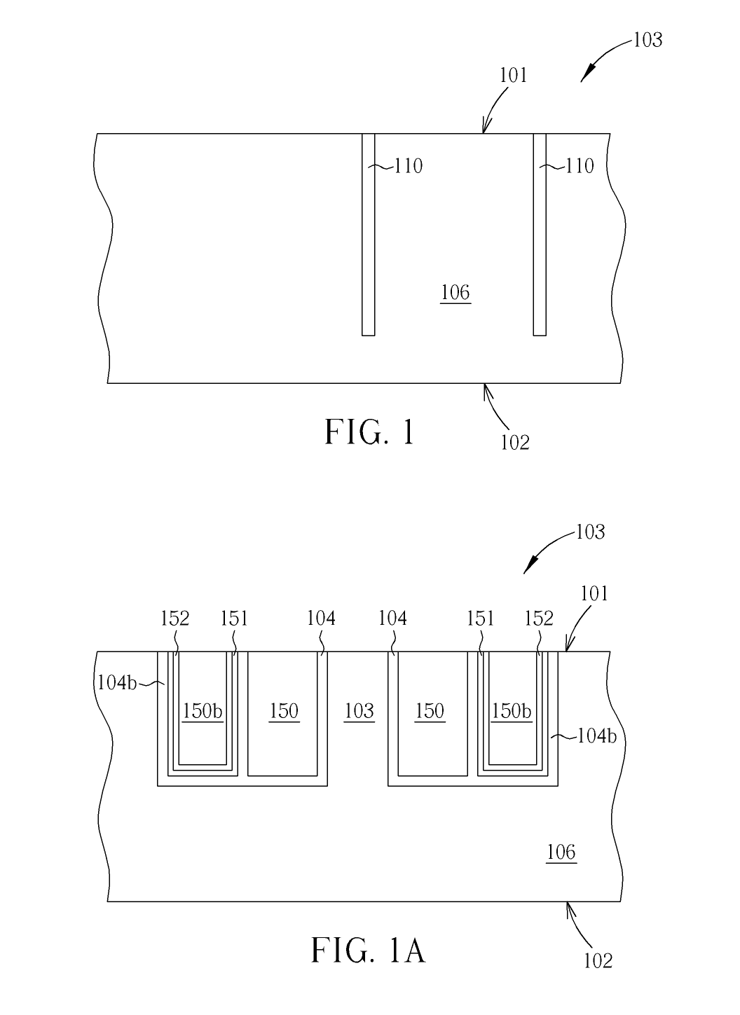

Please refer to FIGS. 1-10, illustrating the method for forming a through-silicon via (TSV) structure of the present invention. Because the method for forming a through-silicon via (TSV) structure of the present invention may form various and different through-silicon via structures, the method of the present invention may have various and different embodiments. First, please refer to FIG. 1, a wafer 103 is provided. The wafer 103 is for use in forming a through-silicon via structure and includes a semiconductor substrate 106. The wafer 103 includes a first side 101 and a second side 102 which is opposite to the first side 101. The first side 101 may be a front side of a semiconductor substrate 106 for the preparation of various semiconductor elements and metal interconnection. The second side 102 may be a bottom side of a semiconductor substrate 106. The semiconductor substrate 106 maybe Si.

Second, in a first embodiment, an annular dielectric layer 110 is formed in the wafer 103. The annular dielectric layer 110 may be formed along with the formation of the shallow trench isolation (not shown). For example, lithographic and etching steps may be used to form recesses (not shown) in the wafer 103 to respectively define the annular dielectric layer 110 and the shallow trench (not shown). The size of the openings on the reticle and etching recipes may be used to control the depth of the recesses and the shallow trenches. Preferably, the depth of the recesses should be deeper than that of the shallow trenches. Later, a dielectric material, such as silicon oxide, may be used to fill the recesses and the shallow trenches, followed by planarization to respectively obtain the annular dielectric layer 110 and the shallow trench isolation (not shown). Optionally, the ring thickness of the annular dielectric layer 110 may be 2 μm-3 μm.

Please refer to FIG. 1A, in a second embodiment a recess (not shown) is etched in the wafer 103 to accommodate the through via dielectric ring, a first conductive ring and a first dielectric ring which are formed in later steps. The recess (not shown) maybe formed along with the formation of the shallow trench isolation (not shown). After the recess (not shown) is formed, an isolation layer 104 is formed on the inner wall of the recess (not shown) and later a conductive material fills the recess (not shown) to form a conductive layer 150, such as by deposition to fill up the recess (not shown). After the isolation layer 104 and the conductive layer 150 are done, some of the substrate in the wafer 103 is disposed between the isolation layer 104 and the conductive layer 150.

Before the conductive layer 150 fills the recess (not shown), at least one of a barrier layer (not shown) and a seed layer (not shown) may be optionally formed on the inner wall of the isolation layer 104. When the conductive layer 150 includes copper, the barrier layer (not shown) may keep the copper from experiencing adverse diffusion. In another aspect, the seed layer (not shown) is useful in inducing the deposition of the conductive layer 150.

Optionally, as shown in FIG. 1A, at least a set of concentric conductive layer and dielectric layer may be formed outside of the isolation layer 104 and the conductive layer 150. For example, a second conductive layer 150b and a second dielectric layer 104b are formed. At this moment, a barrier layer 151 and a seed layer 152 may be optionally formed. On one hand, the second conductive layer 150b surrounds the isolation layer 104. On the other hand, the second dielectric layer 104b surrounds and directly contacts the second conductive layer 150b, and is surrounded by the wafer 103. The method for forming the concentric conductive layer and dielectric layer is described in the previous descriptions and the details will not be elaborated here.

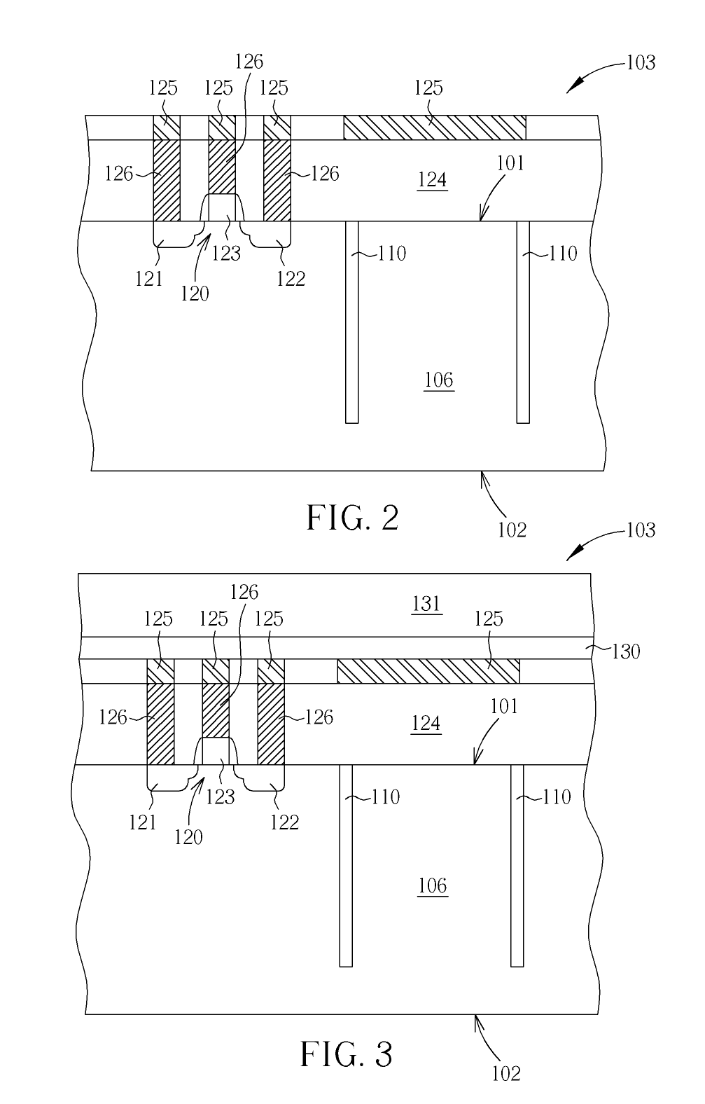

Next, please refer to FIG. 2, a semiconductor procedure is carried out. The semiconductor procedure may be any suitable semiconductor procedure. For example, a semiconductor element 120, such as at least one active element, is accordingly formed on an active region of the first side 101 after this semiconductor procedure. An interlayer dielectric layer 124 is formed on the semiconductor element 120 to cover the semiconductor element 120 as well as an interconnection structure 125 disposed on the interlayer dielectric layer 124 and electrically connected to the semiconductor element 120.

In this embodiment, the semiconductor element 120 may include a gate 123, and a source 121 and a drain 122 disposed adjacent to the gate 123. Optionally, there maybe an etching-stop layer and/or a stress layer formed on the semiconductor element 120 before the interlayer dielectric layer 124 is formed. The interconnection structure 125 penetrates the interlayer dielectric layer 124 and is electrically connected to the corresponding source 121, the drain 122 and the gate 123 on the first side through some contact plugs 126. During the formation of the source 121, the drain 122, the gate 123, the interlayer dielectric layer 124, the interconnection structure 125 and the contact plug 126, at least a thermal step higher than 380° C., such as a high temperature step between 380° C. to 410° C. is carried out. The interlayer dielectric layer 124 may include a dielectric material, such as silicon oxide. The interconnection structure 125 may be a copper damascene conductive structure made by damascene steps. The contact plugs 126 usually include W.

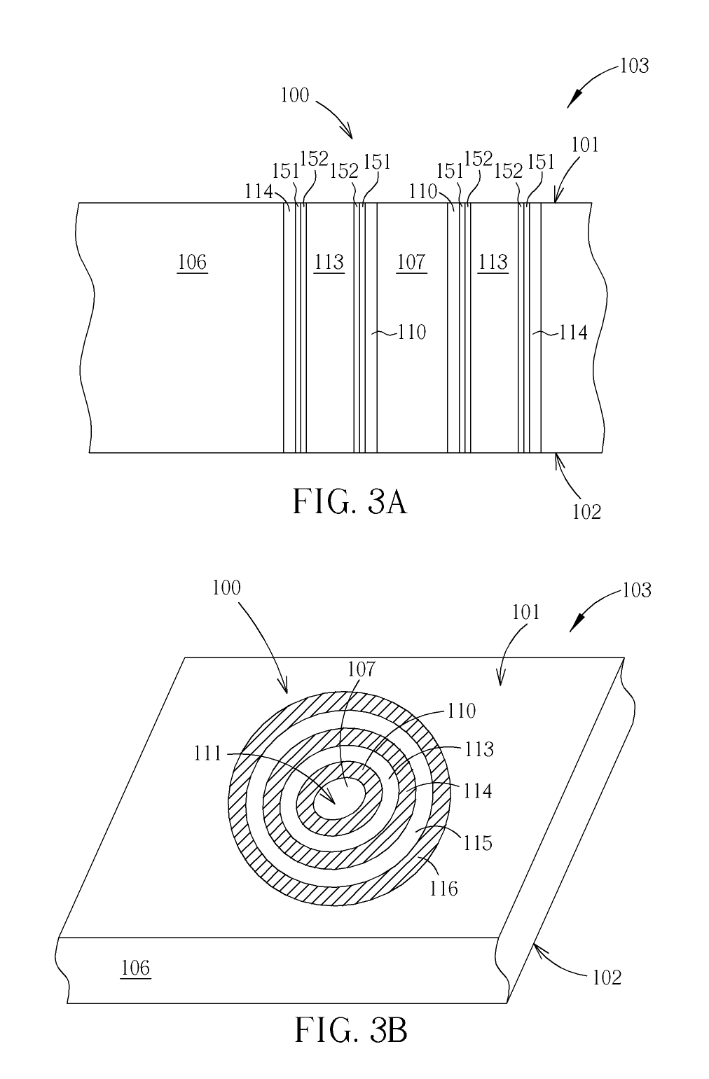

Next, please refer to FIG. 3, the wafer 103 is thinned from the second side 102 to expose the annular dielectric layer 110 so that the annular dielectric layer 110 at this moment becomes a through via dielectric layer 110 after the needed semiconductor elements and the metal interconnection are formed on the first side 101. Part of the wafer 103 may be removed, for example by polishing, to expose the annular dielectric layer 110. Please refer to FIG. 3, an organic material, such as an adhesive 130, is used to attach the first side 101 of the wafer 103 to a carrier 131. Then, a polishing step is carried out to remove part of the wafer 103 so as to expose the annular dielectric layer 110.

Please refer to FIG. 3A, which illustrates the structure of FIG. 1A in which the wafer 103 is thinned. At this moment, the semiconductor substrate 106 becomes a substrate column 107, the isolation layer 104 becomes a through via dielectric ring 110 and a first dielectric ring 114 and the conductive layer 150 becomes a first conductive ring 113. In the through-silicon via structure 100, the first conductive ring 113 surrounds the substrate column 107 rather than the conductive layer 150 is located in the center of the concentric structure. In such a way, the conductive layer 150 may be less expanded or deformed in a thermal step.

If the structure of FIG. 1A has a barrier layer 151 and/or a seed layer 152, the barrier layer 151 and the seed layer 152 are also present in FIG. 3A. Some of the substrate 103, the isolation layer 104 and the conductive layer 150 may be removed by polishing to expose the first conductive ring 113.

FIG. 3B illustrates the results of the wafer 103 which includes the second dielectric layer 104b and the second conductive layer 150b is thinned. FIG. 3B illustrates a concentric structure, which includes a wafer 103, a through via 111, a substrate column 107, a through via dielectric ring 110, a first conductive ring 113, a first dielectric ring 114, a second conductive ring 115 and a second dielectric ring 116. The second conductive layer 150b becomes the second conductive ring 115 and the second dielectric layer 104b becomes the second dielectric ring 116. In the through-silicon via structure 100, the substrate column 107 fills the through via 111 connecting the first side 101 and the second side 102. The second conductive ring 115 surrounds the first dielectric ring 114. The second dielectric ring 116 surrounds and directly contacts the second conductive ring 115, and is surrounded by the wafer 103.

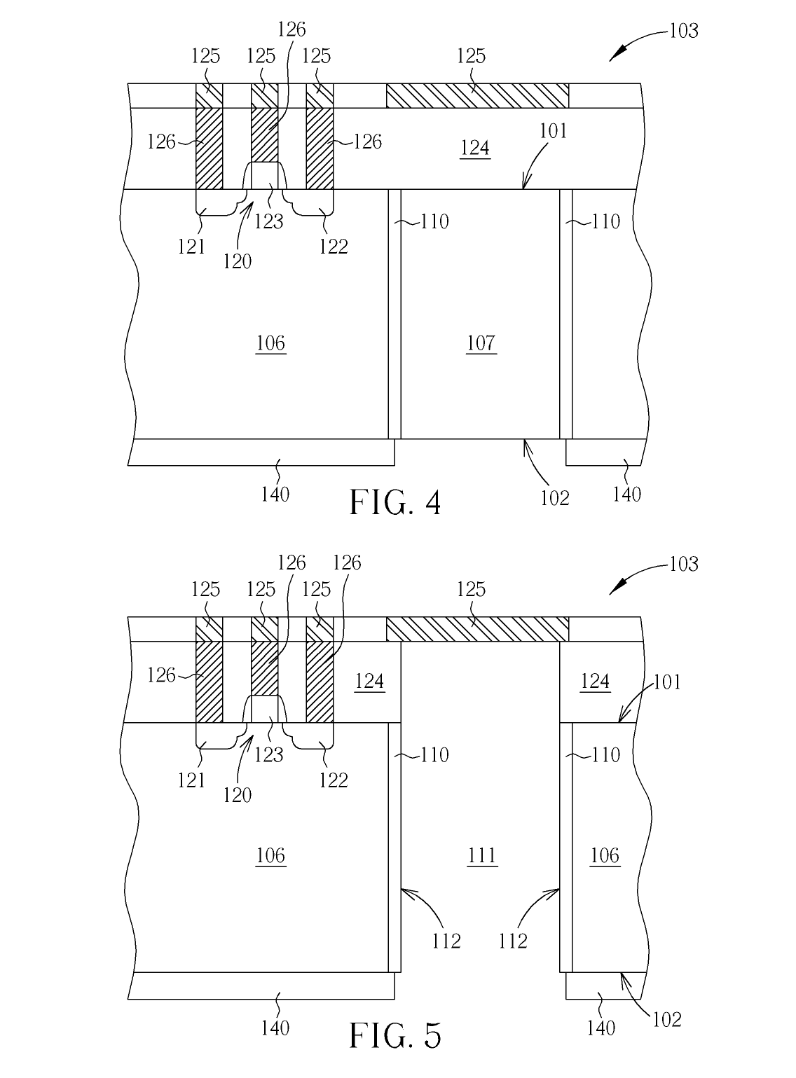

Later, please refer to FIG. 4 a second dielectric layer 140 is formed. The second dielectric layer 140 not only covers the second side 102, but also exposes the annular dielectric layer 110. The steps to form the second dielectric layer 140 may be: a dielectric material, such as silicon oxide or silicon nitride, is first used to completely cover the second side 102 under a low temperature condition, such as lower than 200° C., followed by some lithographic steps along with some etching steps to selectively remove some of the dielectric material, in order to precisely expose the annular dielectric layer 110.

Please note that the second dielectric layer 140 usually does not completely cover the outer surface of the annular dielectric layer 110 due to common misalignment of lithographic steps. The second dielectric layer 140 on one hand does not need to completely cover the outer surface of the annular dielectric layer 110, and on the other hand it does not fail to cover the outer surface of the annular dielectric layer 110 at all. In addition, if the dielectric material covers the second side 102 under a low temperature condition, it may not damage the organic material which attaches the wafer 103 to the carrier 131.

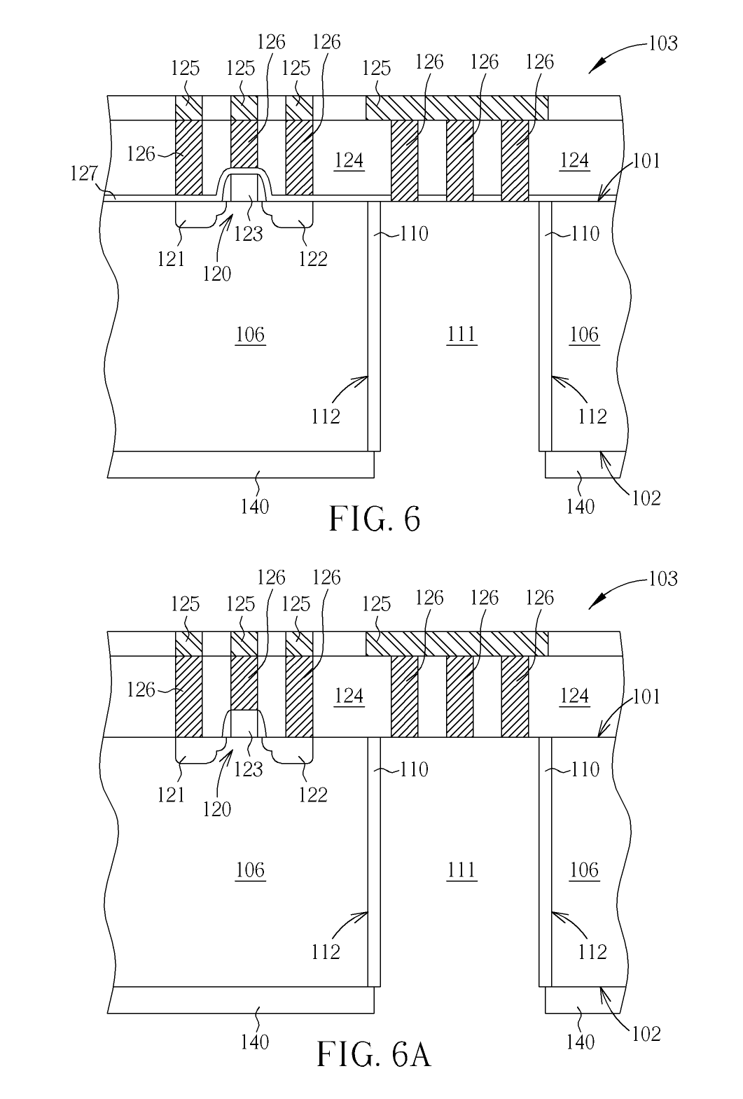

Afterwards, please refer to FIG. 5, the exposed semiconductor substrate 106 within the annular dielectric layer 110 is needed to be completely removed to form a through via 111. When the exposed semiconductor substrate 106 within the annular dielectric layer 110 is being removed, the corresponding interlayer dielectric layer 124 is needed to be completely removed as well so that the two ends of the through via 111 are able to connect the first side 101 and the second side 102. Because the semiconductor substrate 106 within the annular dielectric layer 110 is completely removed, the hollow annular dielectric layer 110 at this moment becomes a through via dielectric layer 110, and simultaneously covers the inner wall 112 of the through via 111. Suitable etching procedure(s), such as a dry etching procedure and/or a wet etching procedure, may be used to completely remove the corresponding interlayer dielectric layer 124 and the semiconductor substrate 106.

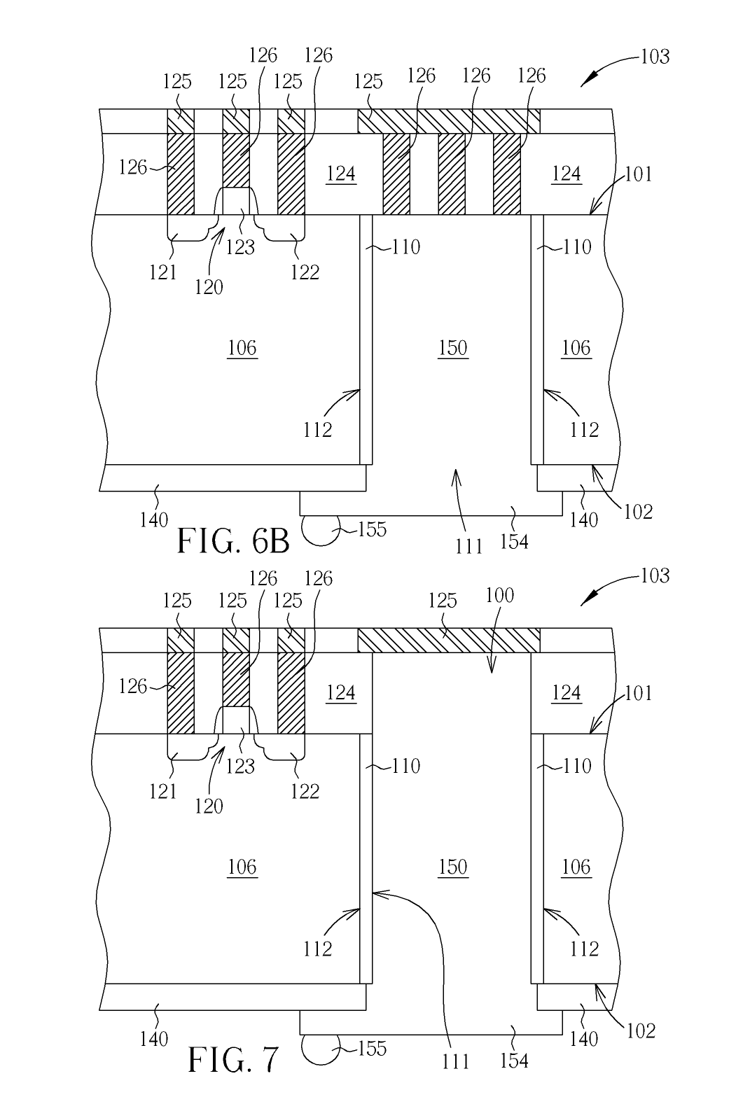

Optionally, the through via 111 may not necessarily expose the interconnection structure 125 to avoid the exposure and contamination of the copper in the through via 111 at the final etching stage. In one embodiment of the present invention, a contact plug 126 may be considered as an alternative indirect medium for electrical connection. For example, as shown in FIG. 6, when the contact plugs 126 are formed, some of the contact plugs 126 may be designed to correspond to the location of the through via 111. Later, when the semiconductor substrate 106 within the annular dielectric layer 110 is completely removed to form the through via 111, such corresponding contact plugs 126 are finally exposed. Preferably, as shown in FIG. 6, there are an etching-stop layer 127 and/or a stress layer 127 disposed on the semiconductor element 120. When the contact plugs 126 are formed, some of the contact plugs 126 may be designed to correspond to the location of the through via 111 and penetrate the interlayer dielectric layer 124 and the etching-stop layer 127 or the stress layer 127. So, part of the etching-stop layer 127 or the stress layer 127 is exposed at the final etching stage. The contact plugs 126 which are in direct contact with the interconnection structure 125 and embedded in the etching-stop layer 127 or the stress layer 127 are also exposed during the final etching stage of the through via 111.

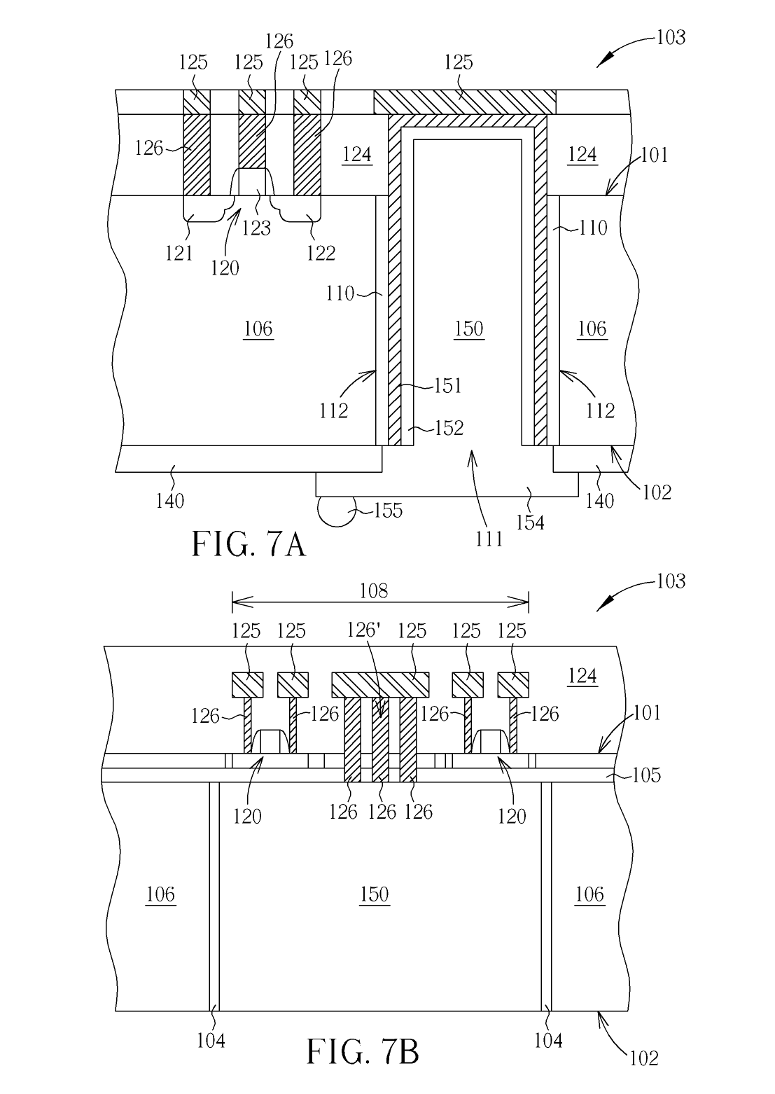

Please refer to FIG. 7, next a conductive layer 150 is used to fill up the through via 111, by deposition for example, and directly or indirectly electrically connected to the interconnection structure 125. Optionally, the conductive layer 150 not only fills up the through via 111, and may extend outwards to cover part of the second dielectric layer 140 to form a connecting pad 154 of pre-determined pattern. The conductive layer 150 usually consists of a single material, such as copper. There is no substrate sandwiched between the conductive layer 150 and the through via dielectric layer 110 to form a seamless through-silicon via structure 100. The conductive layer 150 of the seamless through-silicon via structure 100 may be in a form of a column with a diameter of 18 μm-22 μm. Preferably, the conductive layer 150 is free of a capping structure in any form.

When the conductive layer 150 is directly electrically connected to the interconnection structure 125, the through via 111 directly exposes the interconnection structure 125 when the etching is done so the conductive layer 150 is directly electrically connected to the interconnection structure 125. Part of the conductive layer 150 is surrounded by the interlayer dielectric layer 124 and other conductive layer 150 is surrounded by the through via dielectric layer 110. When the conductive layer 150 is indirectly electrically connected to the interconnection structure 125, as shown in FIG. 7A, contact plugs 126 are previously formed between the interconnection structure 125 and the through via 111 so that the conductive layer 150 is indirectly electrically connected to the interconnection structure 125 by the contact plugs 126. The etching-stop layer 127 or the stress layer 127 is not absolutely necessary, so the contact plugs 126 may be optionally in the etching-stop layer 127 or the stress layer 127.

FIG. 7B illustrates an embodiment in which the wafer 103 is an SOI wafer, so the wafer 103 further includes an isolation layer 105 which covers the first side 101. If there is at least one active element, such as a transistor 120, formed on the active area 108 on the first side 101 of the wafer 103, the active element of the through-silicon via structure 100 of the present invention is just disposed on the isolation layer 105 and right above the conductive layer 150. The size of the conductive layer 150 is usually much larger than that of the active element 120. For example, the total area of the active elements 120 is not greater than one tenth of the cross section area of the conductive layer 150. In addition, there may be an isolation layer 104 disposed between the conductive layer 150 and the semiconductor substrate 106.

The interconnection structure 125 which is disposed in an interlayer dielectric layer 124 may electrically connect to the conductive layer 150 by means of the body contact 126 which is disposed in the active area 106 and penetrates the dielectric layer 105. The body contact 126 may be regarded as a variation of the above-mentioned contact plugs 126 but is much larger than the normal contact plugs 126 in cross section. Preferably, a plurality of body contacts 126 may form a contact plug matrix 126′, for example an n*m matrix. The formation of the body contacts 126 may refer to the description above.

FIG. 7C illustrates an embodiment in which the material for forming the gate 123 of the semiconductor process recited in FIG. 2 may also serve as an etching-stop layer. When the etching step of the semiconductor substrate 106 to be completely removed to form the through via 111 should be precisely controlled, the material for forming the gate 123 may serve as an etching-stop layer. For example, the material for forming the gate 123 is formed on the location in which the through-silicon via structure is about to be formed. The material for forming the gate 123 may be a metal or Si. Also, it is possible that there is a shallow trench isolation 128 disposed under the conductive cap 129. The interlayer dielectric layer 124 partially covers the first side 101.

Later, please refer to FIG. 7C, if the etching step to completely remove the semiconductor substrate 106 to form the through via 111 should be precisely controlled and the problems of over-etching, under-etching, or the etchant damaging the plugs should be avoided, the material for forming the gate 123 may serve as an etching-stop layer to avoid the problems. If the shallow trench isolation 128 is present, the through via 111 may partially penetrate the shallow trench isolation 128. Later when the through-silicon via structure 100 is done, the material which is the same as the conductor of the gate 123 becomes the conductive cap 129. The conductive cap 129 may be a gate electrode as TSV ESL (electronic system-level). The conductive cap 129 is disposed on the first side 101, in the interlayer dielectric layer 124, in direct contact with and completely covers the conductive layer 150. As a result, the area of the conductive cap 129 is larger than that of the conductive layer 150. Because the contact plug 126 electrically connects to the conductive cap 129 and the interconnection structure 125, the interconnection structure 125 is able to electrically connect the conductive layer 150. The conductive cap 129 may include poly Si or a metal material.

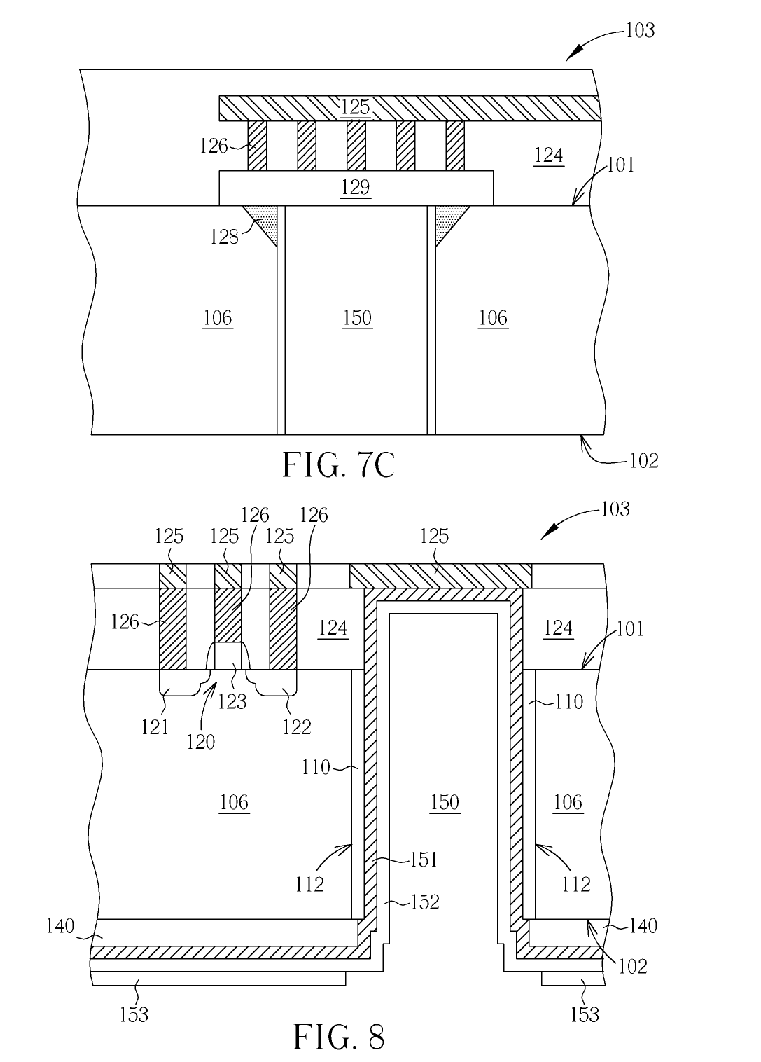

Optionally, as shown in FIG. 8, before the through via 111 is filed up with a conductive layer 150, at least one of a barrier layer 151 and a seed layer 152 may be formed on the through via dielectric layer 110 to cover the surface of the through via dielectric layer 110 and of the second dielectric layer 140. When the conductive layer 150 includes copper, the barrier layer 151 may keep the copper from experiencing adverse diffusion. In another aspect, the seed layer 152 is useful in inducing the deposition of the conductive layer 150. Or, after the formation of the barrier layer 151 and the seed layer 152 but before the formation of the conductive layer 150, a pattered mask 153 for defining a redistribution layer (RDL) may be formed on the barrier layer 151 and the seed layer 152, as shown in FIG. 8. The pattered mask 153 for defining a redistribution layer (RDL) may be a dry film and lithographic and etching procedures may be used to define the needed patterns.

If the barrier layer 151, the seed layer 152 and the pattered mask 153 for defining a redistribution layer (RDL) are present, some of the barrier layer 151, the seed layer 152 and the pattered mask 153 for defining a redistribution layer (RDL) may be removed after the conductive layer 150 fills up the through via dielectric layer 110, to obtain a seamless through-silicon via structure 100 as shown in FIG. 7A. Optionally, there may be bumps 155 formed on the conductive layer 150 to serve as the media for outward electrical connection.

After the previous steps, a resultant seamless through-silicon via structure 100 of the present invention is obtained. As shown in FIG. 7, the wafer 103 includes a semiconductor substrate 106, a first side 101 and a second side 102. The through via 111 is disposed in the wafer 103 to connect the first side 101 and the second side 102. There is a through via dielectric layer 110 in the through via 111 to cover the inner wall 112 of the through via 111. The conductive layer 150 which fills up the through via 111 consists of a single material, such as copper. The conductive layer 150 may be in a form of a column with a diameter of 18 μm-22 μm. A smaller column facilitates to increase the element density of the entire wafer. Preferably, the conductive layer 150 is free of a capping structure in any form. Optionally, the thickness of the through via dielectric layer 110 may be 2 μm-3 μm.

The first dielectric layer 124 and the second dielectric layer 140 respectively cover the first side 101 and the second side 102 of the wafer 103. The first dielectric layer 124 further surrounds part of the conductive layer 150. The second dielectric layer 140 covers the second side 102 and part of the through via dielectric layer 110. However, please notice that the second dielectric layer 140 does not completely but incompletely covers the bottom surface of the through via dielectric layer 110. Moreover, the conductive layer 150 may extend outwards to partially cover the second dielectric layer 140. Please note that the structure is constructed in a wafer rather than formed in a chip. In other words, the present invention is directed to a through-silicon via structure of wafer-level but not to a package-level. There may be bumps 155 formed on the conductive layer 150 to serve as the media for outward electrical connection.

Optionally, there may be at least one of a barrier layer 151 and a seed layer 152 disposed on the inner surface of the through via 111 to cover the through via dielectric layer 110, as shown in FIG. 8. When the conductive layer 150 includes copper, the barrier layer 151 covers and directly contacts the through via dielectric layer 110 so that the barrier layer 151 surrounds and directly contacts the conductive layer 150 to keep the copper from experiencing adverse diffusion. In another aspect, the seed layer 152 is useful in inducing the deposition of the conductive layer 150. If there is no barrier layer 151 and seed layer 152 on the inner surface of the through via 111, the through via dielectric layer 110 is in direct contact with the conductive layer 150. The conductive layer 150 may extend outwards to form a patterned redistribution layer (RDL) 153 and to form a connecting pad 154 with a pre-designed pattern, as shown in FIG. 7 or 7A.

On the first side 101 of the wafer 103, there are semiconductor elements 120, an interlayer dielectric layer 124 covering semiconductor elements 120 and an interconnection structure 125 disposed on the interlayer dielectric layer 124 and electrically connected to the semiconductor elements 120. The semiconductor element 120 includes a gate 123, and a source 121 and a drain 122 disposed adjacent to the gate 123. The interconnection structure 125 penetrates the interlayer dielectric layer 124 and is electrically connected to the source 121, the drain 122 and the gate 123 through contact plugs 126.

The interconnection structure 125 may also be indirectly electrically connected to the conductive layer 150 through contact plugs 126. The interlayer dielectric layer 124 may include a dielectric material, such as silicon oxide. The interconnection structure 125 may be a copper damascene conductive structure made by damascene steps. The contact plug 126 usually includes W. The conductive layer 150 may penetrate the interlayer dielectric layer 124 and be directly electrically connected to the interconnection structure 125, as shown in FIG. 7, or alternatively, indirectly electrically connected to the interconnection structure 125 through contact plugs 126, as shown in FIG. 7A. When the contact plugs 126 are used, the layout pattern on the first side 101 may be in a form of squares of check board or in slots (not shown).

Those skilled in the art will readily observe that numerous modifications and alterations of the device and method may be made while retaining the teachings of the invention.

What is claimed is:

1. A through-silicon via (TSV) structure, in a through via of a wafer, said wafer comprising a first side and a second side and said through via disposed in said wafer and connecting said first side and said second side, said through-silicon via (TSV) structure comprising:
a through via dielectric layer covering the inner wall of said through via;
a conductive layer filling up the through via;
a first dielectric layer covering said first side and surrounding said conductive layer; and
a second dielectric layer covering said second side and part of said through via dielectric layer but partially covered by said conductive layer.

2. The through-silicon via structure of claim 1, wherein said through via dielectric layer surrounds and directly contacts said conductive layer.

3. The through-silicon via structure of claim 1, further comprising:
a barrier layer covering and directly contacting said through via dielectric layer so that said barrier layer surrounds and directly contacts said conductive layer.

4. The through-silicon via structure of claim 1, wherein said conductive layer is a column with a diameter of 18 μm-22 μm.

5. The through-silicon via structure of claim 1, further comprising:
a semiconductor element comprising a source, a drain and a gate together disposed on the first side of said wafer.

6. The through-silicon via structure of claim 5, further comprising:
an interconnection disposed on said first dielectric layer and respectively electrically connected to said semiconductor element and to said conductive layer.

7. The through-silicon via structure of claim 6, wherein said interconnection has an electrical connection with said conductive layer, and said electrical connection is one of a direct connection in which said conductive layer penetrates said first dielectric layer to directly connect said interconnection and an indirect connection in which said conductive layer is electrically connected to said interconnection by means of a plug.

8. A through-silicon via (TSV) structure, in a through via of a wafer, said wafer comprising a first side and a second side and said through via disposed in said wafer and connecting said first side and said second side, said through-silicon via (TSV) structure comprising:
a through via dielectric layer covering the inner wall of said through via;
a conductive layer filling up the through via;
a first dielectric layer covering said first side; and
a plug penetrating said first dielectric layer to electrically connect said conductive layer.

9. The through-silicon via (TSV) structure of claim 8, further comprising:
an etching stop layer disposed between said wafer and said first dielectric layer and penetrated by said plug.

10. A through-silicon via (TSV) structure, in a wafer and said wafer comprising a first side and a second side and an active area disposed on said first side, said through-silicon via (TSV) structure comprising:
a through via disposed in said wafer and connecting said first side and said second side;
a conductive layer filling up said through via;
a dielectric layer covering said first side;
at least one active element disposed in said active area, on said dielectric layer and right above said conductive layer; and
a body contact disposed in said active area, penetrating said dielectric layer to electrically connect said conductive layer.

11. The through-silicon via (TSV) structure of claim 10, wherein said wafer is an SOI wafer.

12. The through-silicon via (TSV) structure of claim 10, further comprising:
a shallow trench isolation disposed in said active area, on said dielectric layer and penetrated by said body contact.

13. The through-silicon via (TSV) structure of claim 10, wherein said body contact comprises a plurality of conductive plugs.

14. The through-silicon via (TSV) structure of claim 13, wherein said body contact forms a conductive plug matrix.

15. The through-silicon via (TSV) structure of claim 10, wherein the total area of at least one said active element is not greater than one tenth of the cross section area of said conductive layer.

16. The through-silicon via (TSV) structure of claim 10, further comprising:
an interconnection structure disposed in an interlayer dielectric layer and on at least one said active element so that a body contact electrically connects said interconnection structure.

17. A method for forming a through-silicon via (TSV) structure, comprising:
providing a wafer comprising a substrate, a first side and a second side;
forming an annular dielectric layer in said wafer;
forming an interlayer dielectric layer on said first side to cover said annular dielectric layer, and forming an interconnection structure w disposed on said interlayer dielectric layer;
thinning said second side of the wafer to expose said annular dielectric layer, so as to make said expose annular dielectric layer become a through via dielectric layer;
forming a second dielectric layer to cover said second side and to expose said through via dielectric layer;
removing said substrate within the annular dielectric layer entirely to form a through via connecting said first side and said second side, wherein said through via dielectric layer covers an inner wall of said through via; and
forming a conductive layer to fill up said through via, and covering said second dielectric layer, wherein the conductive layer electrically connects said interconnection structure.

18. The method for forming a through-silicon via (TSV) structure of claim 17, further comprising:
forming an etching stop layer on said first side;
forming said interlayer dielectric layer disposed on said etching stop layer;
forming a plug to penetrate said interlayer dielectric layer and said etching stop layer; and
forming said through via to expose the etching stop layer and said plug.

19. The method for forming a through-silicon via (TSV) structure of claim 17, further comprising:
forming said interlayer dielectric layer on said first side; and
forming said through via to penetrate the dielectric layer and to expose said interconnection structure.

20. The method for forming a through-silicon via (TSV) structure of claim 17, further comprising:
forming a conductive cap disposed on said first side;
forming said interlayer dielectric layer and completely covering said conductive cap; and
forming an interconnection structure and a plug disposed in said interlayer dielectric layer, wherein said plug electrically connects said conductive cap and said interconnection structure.
